(19) United States
(12) Patent Application Publication
(10) Pub. No.: US 2023/0183850 A1
(43) Pub. Date: Jun. 15, 2023

(54) METHOD OF PREPARING NANOWIRE NETWORKS AND NETWORKS PREPARED THEREBY

(71) Applicant: The Provost, Fellows, Foundation Scholars, and the other Members of Board, Of The College Of The Hol, Dublin 2 (IE)

(72) Inventors: Emmet SHEERIN, Dublin 2 (IE); John BOLAND, Dublin 2 (IE); Prabhava S. N. BARIMAR, Dublin 2 (IE)

(21) Appl. No.: 17/998,360

(22) PCT Filed: May 10, 2021
(86) PCT No.: PCT/EP2021/062365

§ 371 Date: Nov. 10, 2022

(30) Foreign Application Priority Data
May 11, 2020 (GB) GB2006924.1

(51) Int. Cl. C23C 14/04; H01B 13/00; C23C 14/30; C23C 14/20

(52) U.S. Cl. CPC C23C 14/04; H01B 13/0036; C23C 14/30; C23C 14/20; D01D 5/003

(57) ABSTRACT

The present invention relates to methods of preparing nanowire networks, as well as to nanowire networks prepared thereby. The method comprises (a) providing a substrate coated with a film of a first polymer; (b) depositing nanofibers of a second polymer onto the film to form a patterned layer comprising a nanofibre network structure; (c) depositing a layer of a first metal onto the patterned layer; (d) performing a solvent development step to selectively remove the nanofibers leaving a negative pattern exposing the first polymer film; (e) performing an etching step to remove the exposed polymer film; (f) depositing a second metal or oxide thereof onto the negative pattern to form a tem plated nanowire network; and (g) performing a lift-off step to expose the nanowire network.

The present invention relates to methods of preparing nanowire networks, as well as to nanowire networks prepared thereby.

Materials which possess both optical transparency and electrical conductivity are known as transparent conductors (TCs) and are essential components in many commonplace optoelectronic devices such as touchscreen panels, photovoltaic cells, photodetectors and LEDs. The most commonly used material for TCs is traditionally ITO (indium tin oxide), due to its high visible light transmission and tuneable sheet resistance. However, ITO suffers from a number of disadvantages, such as the scarcity of indium, poor transparency to UV and IR wavelengths, and poor sputtering characteristics. The brittle mechanical behaviour of ITO also makes it unsuitable for use in certain optoelectronic devices and with flexible substrates. These, and other disadvantages have motivated the search for alternative transparent conductor materials which demonstrate good performance characteristics in terms of transmission and conductivity.

Nanowire networks (NWNs) are promising materials for next generation optoelectronic devices. However, to date, the feasibility of preparing NWNs for device manufacture on an industrial scale has not been demonstrated and the commercial-scale production of these structures remains limited by a number of factors including, for example, reliance upon slow direct-write lithography steps, or the requirement for free-standing transfer processes.

Wu et al. (Wu, H., et al. Nature Nanotech 8, º 21-º 25 (2013) reported the fabrication of a free-standing nanofibre network, subsequent metal deposition and stamp transfer onto a supporting substrate. These nanowires have a distinctive C-shaped cross-section and require a transfer step which invariably leads to a degree of damage to the network. The deposition of metal directly onto the polymer fibre also results in poor metal quality.

He et al. (ACS Nano 201º, 8, 5, º 782-º 789) reported a process comprising depositing a Cu film on a substrate, patterning with nanofibres, and chemical etching to transfer the network pattern onto the metal film. This chemistry described in this paper is specific to copper, and only works for large fibre widths (^{˜}1 μm). The resulting wires have rough edges, low width-height ratios and suffer from poor performance characteristics.

Yang et al. (ACS Appl. Mater. Interfaces 2018, 10, 1996-2003) disclose a method for the preparation of a gold NWN using an electrospun polymer fibre network as a mask. In this method, a network of fibres is deposited onto a substrate, followed by the deposition of an aluminium film. A solvent development step is used to remove the nanofibers, leaving a negative of the network pattern formed by exposed substrate. Gold is then deposited before an acid etching lift-off step is carried out to remove the aluminium and expose the gold nanowire network. High device performance has been demonstrated with this technique. However, the aggressive acid lift-off step renders this technique unsuitable for use with other metals, limiting its feasibility to the formation of gold networks.

It is an aim of the invention to obviate or mitigate one or more of the disadvantages associated with the prior art. A scalable method for the preparation of conductive NWNs would be beneficial. A method for the preparation of NWNs with improved performance characteristics and/or tuneable optical and electrical behaviours would be particularly advantageous, as would a cost-effective method for producing same. A method which could be used to form conductive NWNs of a variety of materials would also be particularly beneficial.

### SUMMARY

Accordingly, the present invention relates to methods of preparing conductive NWNs, such as transparent conductive nanowire networks, in which networks of polymer nanofibers are fabricated and used as a sacrificial template in a pattern transfer process. The polymer nanofibers are used to map the nanofibre network structure onto a polymer-coated substrate. The nanofibre polymer and the substrate-coating polymer are selected such that they have orthogonal solubilities—this can be exploited to allow accurate mapping of the nanofibre network structure onto a template for metal deposition, whilst facilitating removal/“lift-off”) of the network from the template—the lift-off step can be carried out under mild conditions using a solvent chosen to dissolve the polymer coating, rendering the process suitable for use with a wide variety of materials, such as, for example gold, silver, copper, nickel, titanium, chromium, silicon, titanium dioxide, silicon dioxide and nickel oxide. NWNs prepared by this novel method demonstrate excellent performance characteristics when compared with known NWN materials, while the use of established and robust physical chemistry techniques facilitates scale-up of the process. Advantageously, the process can be used with a variety of substrates, including flexible substrates.

In a first aspect of the present invention there is provided a method of preparing a conductive nanowire network, the method comprising:

(a) providing a substrate coated with a film of a first polymer;

(b) depositing nanofibers of a second polymer onto the film to form a patterned layer comprising a nanofibre network structure;

(c) depositing a layer of a first metal onto the patterned layer;

(d) performing a solvent development step to selectively remove the nanofibers leaving a negative pattern exposing the first polymer film;

(e) performing an etching step to remove the exposed polymer film;

(f) depositing a second metal or oxide thereof onto the negative pattern to form a templated nanowire network; and

(g) performing a lift-off step to expose the nanowire network.

In an embodiment, the substrate coated with a film of a first polymer has been formed by spin coating.

Spin coating is a solution-based technique which is used for the formation of polymer films. Using spin-coating, the thickness of the film can be tailored by controlling parameters such as the spin speed and the concentration of the polymer and is also dependent on the molecular weight of the polymer being coated. Preferably, the thickness of the coating is from approximately 150 nm to 1 μm, from 200 nm to 800 nm or from 200 to 500 nm, depending on application requirements.

In an embodiment, the first polymer is selected from polystyrene (PS) and polymethylmethacrylate (PMMA).

In an embodiment, the step of depositing nanofibers of a second polymer onto the film is performed by electrospinning.

Electrospinning is a technique used for the formation of uniform fibres which works by drawing a polymer solution through a narrow opening held at high electrical potential. Electrospinning is a suitable technique for the deposition of the nanofibres in the process of this invention as it can be used to form defect-free fibres with uniform diameters. Electrospinning also allows the average diameter of the fibres, and hence the network nanowires to be controlled, allowing for controlled network development.

In an embodiment, the electrospinning step utilises a collector stage with a plate or ring stage geometry.

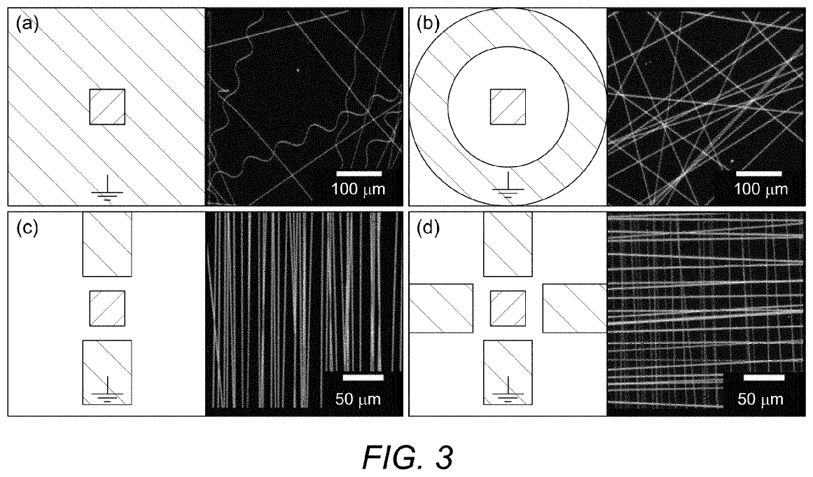

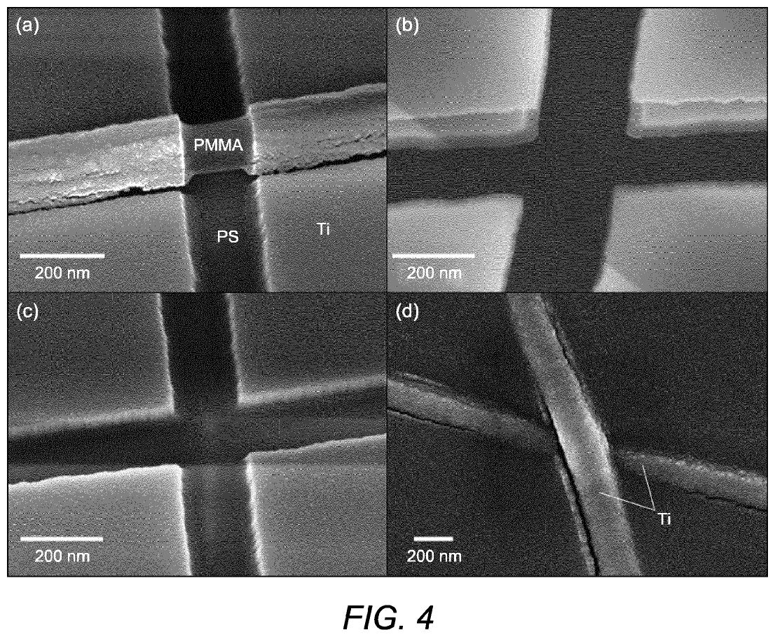

As would be understood by one of skill in the art, a “plate” or “flat plate” stage geometry comprises a simple plate configuration in which the sample is placed at the centre of a grounded copper plate, while a “ring” collector stage consists of a grounded copper ring on an insulating Teflon base with the sample placed at the centre of the ring. Representations of these configurations are shown in FIG. 3.

In an embodiment, the second polymer is selected from polymethylmethacrylate (PMMA), polyvinyl alcohol (PVA), polyvinyl pyrrolidone (PVP), polyethylene oxide (PEO) and polyvinyl acetate (PVAc).

In an embodiment, the step of depositing a layer of a first metal onto the patterned layer is performed by a vacuum deposition process or an atmospheric deposition process.

In an embodiment, the step of depositing a second metal or oxide thereof onto the negative pattern is performed by a vacuum deposition process or an atmospheric deposition process.

The deposition process may independently be a vacuum deposition process or an atmospheric deposition process for one or both of these steps. Suitable vacuum deposition processes include, but are not limited to, e-beam, thermal, sputtering, and pulsed laser deposition. Suitable atmospheric deposition processes include dip-coating, spray coating, atmospheric pulsed laser deposition, or it could be carried out by powder filling followed by laser/thermal annealing; as would be understood by one skilled in the art.

In embodiments, the process may be a vacuum deposition process. The vacuum deposition process may be e-beam vapour deposition.

The quality of metal films deposited using physical vapour deposition methods depends on a number of parameters, including, for instance, vacuum pressure, film thickness, substrate material and temperature, deposition rate and residual gas composition and such parameters can be optimised for use with this process when a physical vapour deposition technique is used as would be understood by a person skilled in the art.

In an embodiment, the first metal is selected from titanium, chromium, cobalt, gold, palladium, platinum, silver, tantalum, tungsten and silicon.

In an embodiment, the first metal is titanium.

A solvent development step is performed after the first metal has been deposited using a development solvent to selectively dissolve the nanofibres. In the process of the present invention, the first polymer and the second polymer are different. The first polymer and the second polymer are selected such that they have orthogonal solubilities. This allows the sacrificial nanofibres to be dissolved without damaging (e.g. swelling or dissolving) the underlying polymer film which coats the substrate. As an illustrative example, polystyrene (PS) can be used as the first polymer and polymethylmethacrylate (PMMA) as the second polymer. In this illustrative example, acetic acid can be used to selectively dissolve the nanofibres (i.e. as the ‘development solvent’)—acetic acid is an excellent solvent for PMMA and a non-solvent for PS, and so readily dissolves the nanofibres while leaving the patterned film intact.

In an embodiment, the first polymer is polystyrene and the second polymer is polymethylmethacrylate (PMMA); the first polymer is polymethylmethacrylate (PMMA) and the second polymer is polyvinyl alcohol (PVA); the first polymer is polymethylmethacrylate (PMMA) and the second polymer is polyvinyl pyrrolidone (PVP), the first polymer is polymethylmethacrylate (PMMA) and the second polymer is polyethylene oxide (PEO); or the first polymer is polymethylmethacrylate (PMMA) and the second polymer is polyvinyl acetate (PVAc).

The solvent which is used in the solvent development step to selectively remove/dissolve the nanofibres is hereinafter referred to as the ‘development solvent’. The development solvent is selected such that it dissolves the second polymer but does not dissolve the first polymer. The choice of development solvent will therefore depend on the polymers and it is within the remit of a skilled person to select a suitable development solvent for the polymer system used; however as illustrative examples, the development solvent can be selected from acetic acid, water and ethanol. For instance, acetic acid can be used as the development solvent for a PS (first polymer)/PMMA (second polymer) system; water can be used as the development solvent for a PMMA (first polymer)/PVA (second polymer) system; and ethanol can be used for PMMA (first polymer)/PVP (second polymer), PMMA (first polymer)/PEO (second polymer) and PMMA (first polymer)/PVAc (second polymer) systems.

After the development step has been performed, an etching step is carried out to remove the areas of the first polymer film which have been exposed by removal of the nanofibres. In an embodiment, the etching step is performed by plasma etching. The plasma etching may be oxygen plasma etching. Oxygen plasma etching is particularly suitable for use with this process, as it efficiently removes the exposed polymer as well as forming an overhang which leads to a clean lift-off. Oxygen plasma etching also additionally cleans the substrate for deposition.

In an embodiment, the etching step can be performed in one or more stages. In an embodiment, the etching step can be performed in two stages.

The second metal or metal oxide is not particularly limited once it is capable of being deposited in accordance with the method of the invention. As previously described, deposition can be carried out, for example, by a physical vapour deposition (PVD) system or an atmospheric deposition system. Suitable examples of the second metal or metal oxide include, but are not limited to aluminium, platinum, gold, silver, copper, nickel, titanium, chromium, silicon, titanium dioxide, silicon dioxide and nickel oxide. This highlights the versatility of the method of the invention which can be used to form nanowire networks of a variety of materials.

In an embodiment, the second metal is aluminium.

Aluminium is a particularly suitable material for use in this process as, in terms of bulk resistivity, it ranks fourth overall, displaying a bulk resistivity only ˜1.7 times higher than silver, while being one of the earth's most abundant elements, it is available at a raw cost of less than 0. º % of that of silver (Ryan K. Zinke, W. H. W., Mineral Commodity Summaries 2018. Interior, U.S.D.o.t.l., Ed. https://doi.org/10.3133/7019*932, 2018). Aluminium also passivates in air to form a thin, highly stable surface oxide which protects the underlying metal from corrosion. Despite these advantages, only limited reports have been made to date of networks of aluminium wires as TCs and these have generally demonstrated insufficient performance to enable their use in commercial applications.

Once the nanowire network has been formed on the template, a lift-off step is performed to expose the metal nanowire network. During the lift-off process, the remaining first polymer coating is removed with solvent (hereinafter the ‘lift-off solvent’), taking the remaining first metal with it, and leaving only the conductive NWN on the substrate.

In an embodiment, the lift-off step comprises immersing the templated NWN network in a lift-off solvent.

As would be appreciated by one skilled in the art, suitable lift-off solvents should dissolve the first polymer without damaging the conductive nanowire network or substrate. Such solvents would be known to one skilled in the art, and include, for example, acetone and N-methyl-2-pyrrolidone (NMP). Advantageously, this lift-off step is carried out under mild conditions and avoids the need for aggressive acid etching, as in previously known techniques. This means that the method can be used to form conductive metal networks for a range of metal/metal oxide materials, and is not limited to those metals which are resistant to acid corrosion or other aggressive techniques.

In an embodiment, the first polymer is polystyrene (PS), the second polymer is polymethylmethacrylate (PMMA), and the lift off solvent is N-methyl-2-pyrrolidone (NMP); the first polymer is polymethylmethacrylate (PMMA), the second polymer is polyvinyl alcohol (PVA), and the lift-off solvent is acetone; the first polymer is polymethylmethacrylate (PMMA), the second polymer is polyvinyl pyrrolidone (PVP) and the lift-off solvent is acetone; the first polymer is polymethylmethacrylate (PMMA), the second polymer is polyethylene oxide (PEO) and the lift-off solvent is acetone; or the first polymer is polymethylmethacrylate (PMMA), the second polymer is polyvinyl acetate (PVAc) and the lift-off solvent is acetone.

Exemplary systems which can be used in the process are as follows:

TABLE 1
Exemplary polymer/solvent systems

| | | Development | Lift-off |
|---|---|---|---|
| First Polymer | Second Polymer | solvent | solvent |
| PS | PMMA | Acetic acid | NMP |
| PMMA | PVA | Water | Acetone |
| PMMA | PVP | Ethanol | Acetone |
| PMMA | PEO | Ethanol | Acetone |
| PMMA | PVAc | Ethanol | Acetone |

The substrate may be a rigid substrate or a flexible substrate. The substrate may be selected from glass, quartz or plastic materials such as polypropylene, polyethylene, polyethylene terephthalate (PET) or polyethylene naphthalate (PEN). When the lift-off solvent is NMP, the substrate may be glass or quartz. When the lift-off solvent is NMP, the substrate may be PEN. Thus, when the first polymer is PS and the second polymer is PMMA, a glass, quartz or PEN substrate may be preferred.

In an embodiment, the method further comprises the step b(1) of annealing the patterned layer.

Incorporating an optional additional step of annealing the patterned layer after the nanofibers have been deposited onto the film, softens the fibres and ensures that they lay flush with the film surface. This can help to prevent the metal which is deposited in step (c) from partially diffusing under the fibre edges during deposition, and minimises narrowing or necking defects in the resultant structure.

### EXAMPLES

The invention will now be described by way of example only with reference to the accompanying figures, in which:

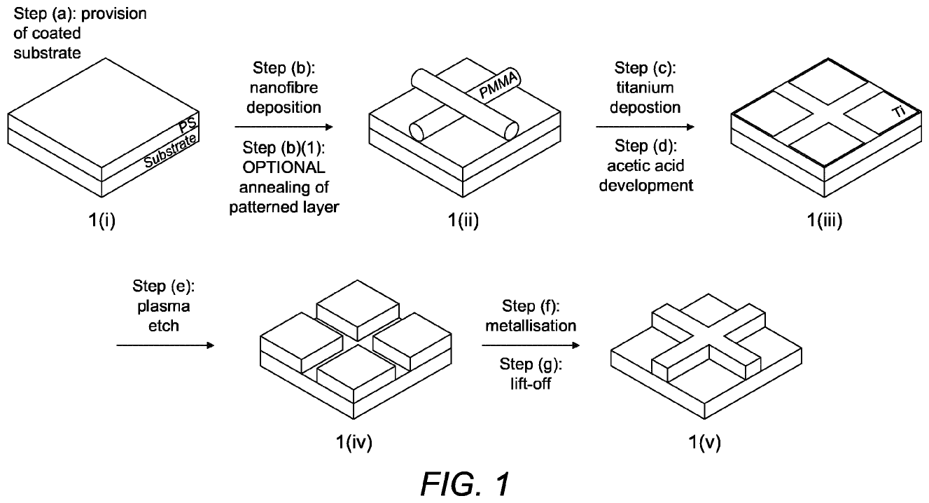

FIG. 1 illustrates a schematic of a method according to an embodiment of the invention;

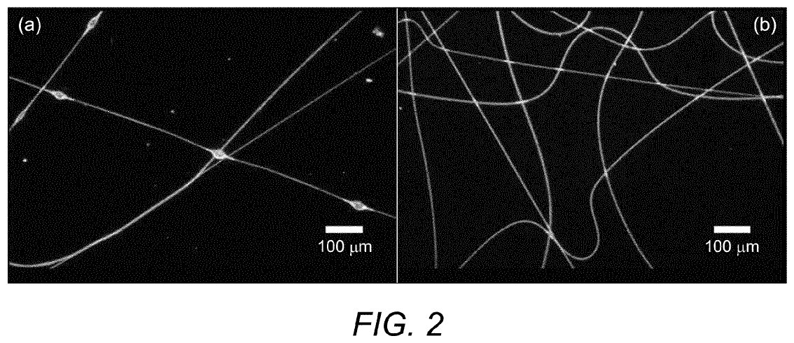

FIG. 2 shows optical dark field images of PMMA nanofibres spun from (a) 8% (w/v) and (b) 10% (w/v) PMMA in DMF;

FIG. 3 illustrates (a) plate; (b) ring; (c) parallel-strip and (d) cross-strip stage geometries for electrospinning and the fibre network morphology formed from each;

Figure º shows SEM image of PMMA nanofibre on PS film after Ti deposition (overlying fibre at junction lifted out of view due to charging); (b) developed (after using development solvent) Ti-PS templates without optional annealing step; (c) developed (after using development solvent) T-PS template after annealing step carried out at 80° C. for 5 minutes; and (d) developed T-PS template after annealing step carried out at 100° C. for 5 minutes;

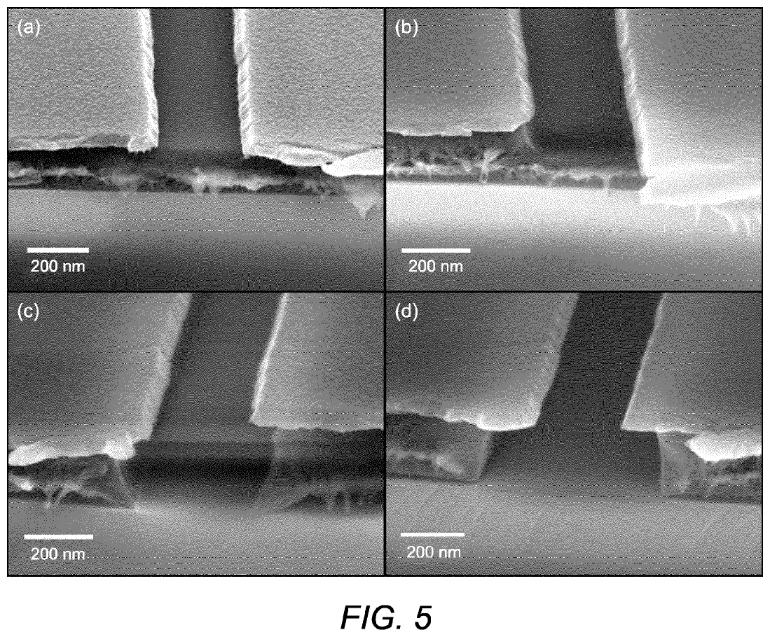

FIG. 5 shows (a) unetched Ti-PS template edge immediately after development; (b) Ti-PS template after a single 15 minute etching step; (c) Ti-PS template after a single 30 minute etching step; (d) Ti-PS template after two 30 minute etching steps; and (e) damaged Ti-PS template after a single 60 minute oxygen plasma etching step;

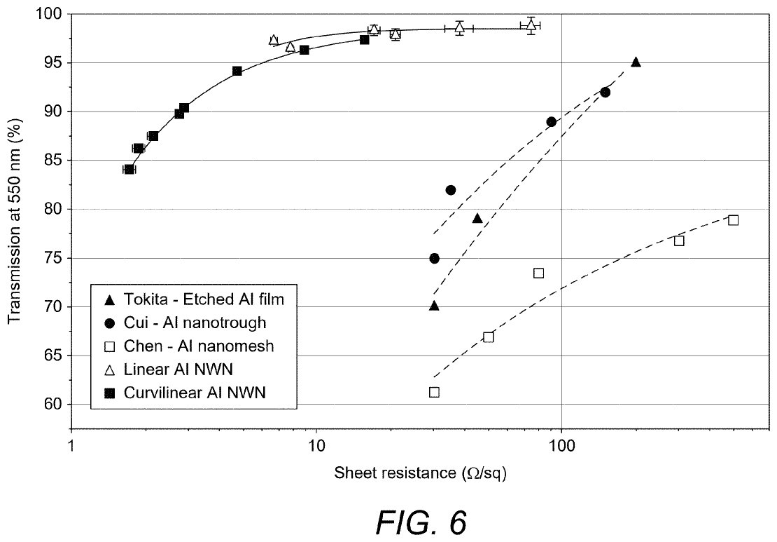

FIG. 6 shows the comparison of the specular transmittance and sheet resistances measured for 190 nm thick linear and curvilinear aluminium NWNs prepared according to embodiments of the invention with aluminium nanowire-based TC materials prepared in accordance with literature publications; and

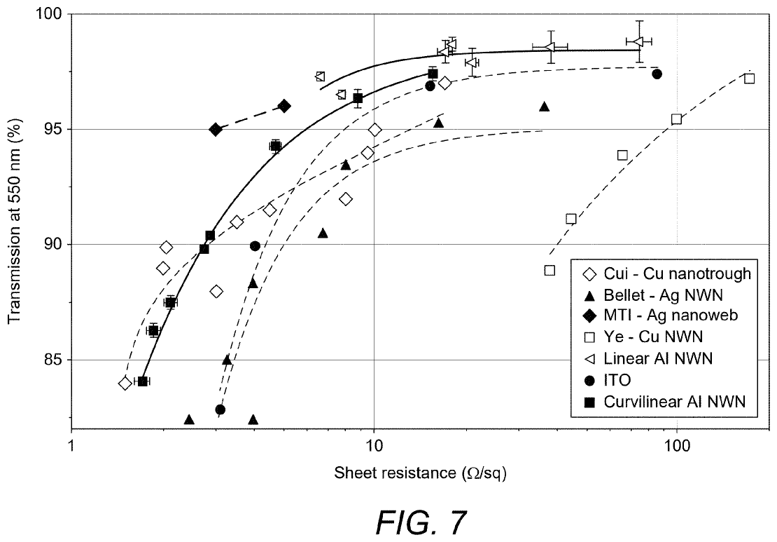

FIG. 7 shows the comparison of the specular transmittance and sheet resistances measured for 190 nm thick linear and curvilinear aluminium NWNs prepared according to embodiments of the invention with commercial ITO films and a selection of the best-performing TCs prepared in accordance with literature publications;

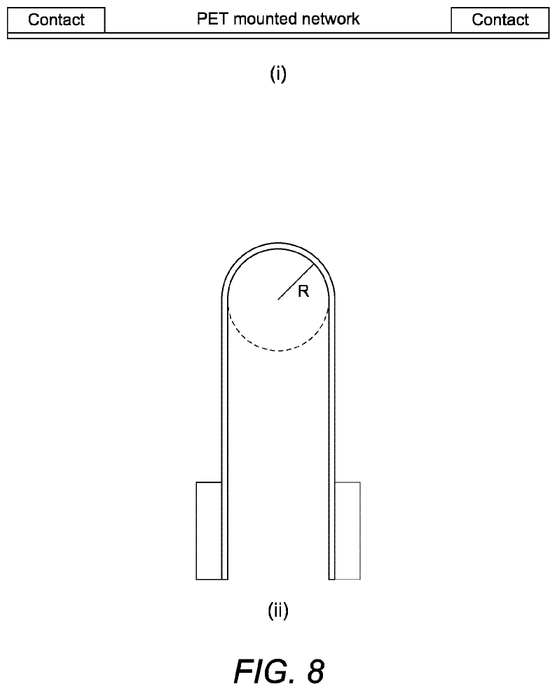

FIG. 8 shows the set-up of a device used to measure device performance during flexing, with 8(i) showing the device in a flat state, and 8(ii) the device flexed to bending radius R=5 mm;

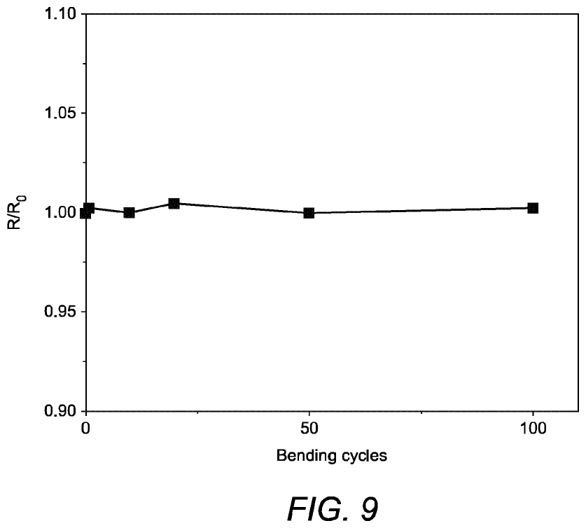

FIG. 9 shows sheet resistance change as a function of bending cycles for an aluminium nanowire network on a PET substrate in accordance with the invention.

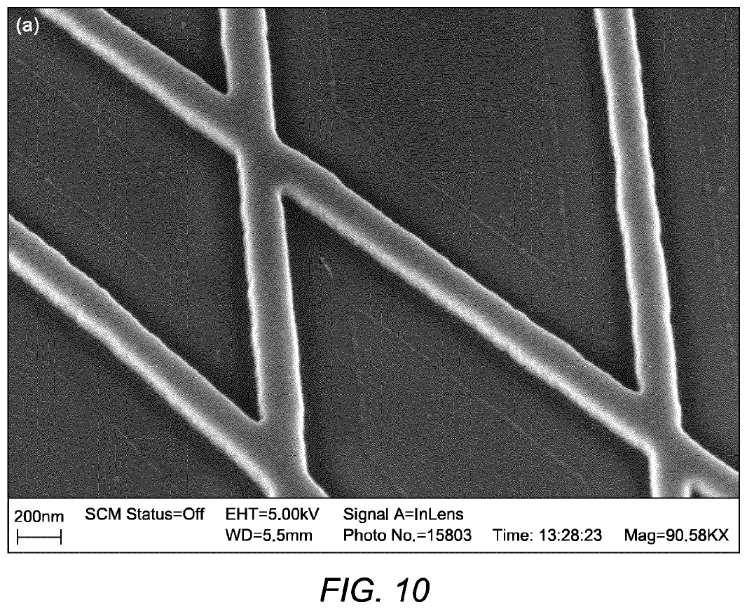

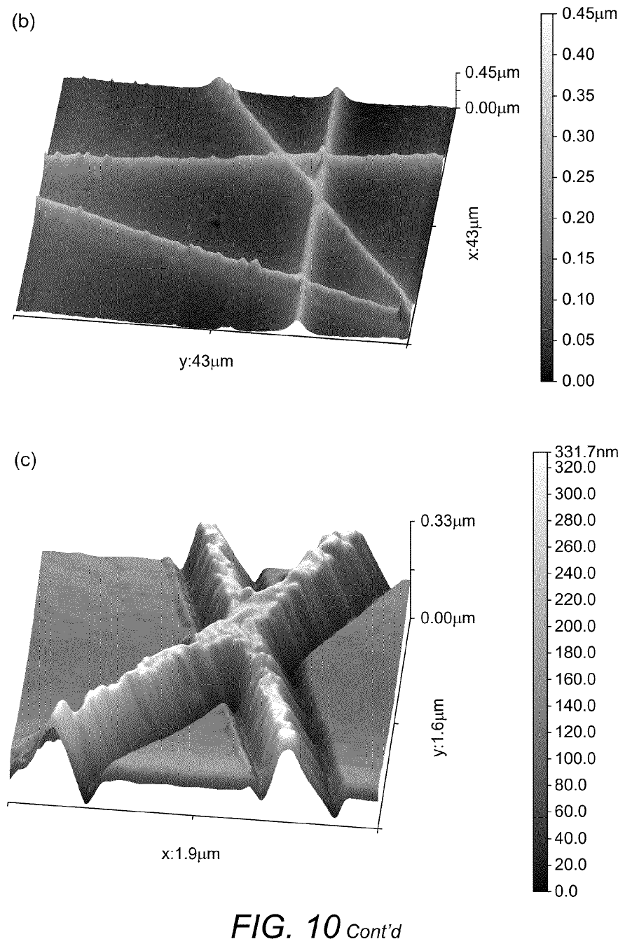

FIG. 10 shows AFM images of (a) glass-based Copper, (b) PET-based Aluminium and (c) PEN-based Aluminium networks prepared in Example 12.

### DETAILED DESCRIPTION

An embodiment of the invention will now be described in detail with reference to FIG. 1. Step (a) shows the provision of a transparent substrate coated with a 300 nm film of polystyrene (PS). Although not shown, the film had been coated from a 6% (w/v) solution of 150 k polystyrene spin-coated onto a substrate at º, 000 rpm. In step (b), PMMA nanofibres are deposited on the surface of the polystyrene to form a network pattern. Although not shown, an optional annealing step can be performed once the nanofibres have been deposited to ensure good adhesion between the nanofibres and the PS and prevent metal diffusion under the fibre edges during subsequent deposition steps. FIG. 1(ii) shows the resultant patterned layer comprising a nanofibre network structure. In step (c) a layer of titanium is then deposited on the surface using e-beam vacuum deposition. In step (d), a solvent development step, in this case using acetic acid, is then performed to selectively dissolve the PMMA nanofibres without swelling or damaging the polystyrene (PS), forming a negative pattern where the sacrificial nanofibres have been removed exposing the polystyrene underneath (FIG. 1(iii)). An optional step (not shown) of agitating in deionised water can be carried out at this point if desired to ensure removal of any stray titanium fragments. In step (e), a plasma etching step is performed to remove the exposed polystyrene (PS), leaving an etched titanium/polystyrene pattern on the substrate surface (FIG. 1(iv)). In step (f), a deposition step is used to metallise the pattern and form the conductive metal network, before a solvent lift-off step, step (g), dissolves the titanium/polystyrene pattern exposing the seamless conductive metal network (FIG. 1(v)).

### EXAMPLES

The invention will now be fully described with reference to the following illustrative examples.

### Example 1: Nanofibre Deposition

Electrospinning experiments used 350 k Mw PMMA supplied by Sigma Aldrich in powder form. Solutions of PMMA in dimethylformamide (DMF) were prepared by stirring at 60° C. overnight then allowing to cool to room temperature before use. The onset of jet formation was observed at 10 kV using a 12 cm tip collector distance (TCD), 1 ml/hr flow rate and a 25G stainless steel needle.

### Example 1(i): Effect of Varying Polymer Concentration

The effect of varying polymer concentration on the electrospun nanofibres was studied by preparing varying concentrations of PMMA in DMF. While beads appeared in the fibre structures with increasing frequency as the concentration of PMMA was decreased (see FIG. 2(a) showing ‘beading’ in nanofibres spun from 8% (w/v) solution; solutions of 10% (w/v) PMMA yielded defect-free fibres with uniform diameters (see FIG. 2(b)). The smallest bead-free PMMA fibres had diameters of 1316±297 nm.

### Example 1(ii): Effect of Adding Surfactant to Solvent System

In order to ascertain whether narrower fibre diameters could be obtained, the effect of adding a surfactant was investigated by adding cetyltrimethylammonium bromide (CTAB) to the solvent system. CTAB (≥99% BioXtra grade) was supplied by Sigma Aldrich in fine powder form. The relationship between fibre diameter (measured from a sample of 30 fibres per test) and CTAB content for a 10% solution of PMMA was measured for CTAB concentrations of 0.1, 0.5, 1 and 5% (w/w) CTAB. Results showed a sharp decrease in average fibre diameter with the addition of CTAB, which levelled off beyond 1% with no further reduction in fibre diameter with increasing CTAB concentration.

The relationship between average fibre diameter (measured from a sample of 30 fibres per test) and PMMA concentration was measured for both pure DMF solvent and 5% CTAB/DMF-solvent systems. Solutions were electrospun at 10 kV, 12 cm TCD, 1 ml/hr flow rate with an 18G stainless steel needle. For PMMA solutions based on pure DMF, beaded fibres were observed for PMMA solutions of 8% concentration or less but in the case of the 5% CTAB-DMF solution, the PMMA concentration could be lowered to º % with no observable bead defects, suggesting that CTAB is acting to decrease surface tension and hence reduce the tendency for beading.

### Example 1(iii): Effect of Applied Voltage

The relationship between applied voltage and fibre diameter was also assessed for a 10% PMMA solution in 5% CTAB/DMF. A large increase in the diameter variance was observed at 1º kV. This is attributed to the formation of smaller secondary fibres branching from the body of the primary fibre, likely caused by excessive charge on the fluid jet during electrospinning. No branched fibre structures were observed at applied voltages below 1º kV.

### Example 1(iv): Effect of Tip Width, TCD and Flow Rate

The dependence of the average fibre diameter (measured from a sample of 30 fibres per test) on tip width and on TCD were also investigated. No significant dependence on needle size was evident which is considered typical for polymer electrospinning. A minor trend of increasing average fibre diameter with increasing TCD was noted and attributed to the weaker field strength as the distance from the tip to ground was increased. No other change in fibre morphology was observed while varying either of these parameters. The effect of flow rate on the spinning process was also examined; at rates below 1 ml/hr, the hanging droplet present at the tip was seen to rapidly deplete upon the onset of electrospinning. Fibre formation then halted until additional solution built up a new droplet resulting in a staggered spinning process with fibres depositing in regular bursts. At rates above 1 ml/hr, continuous fibre formation was observed but excess solution accumulated at the tip leading to frequent drops falling on the sample underneath. A flow rate of 1 ml/hr provided enough solution to prevent depletion of the droplet while minimising excess drops.

### Optimised Electrospinning Conditions for Deposition of PMMA Nanofibres

Based on the results, a set of electrospinning conditions was established using a 5% CTAB/DMF solvent system to provide a tuneable process for the production of PMMA nanofibres. Throughout further experiments, electrospinning was carried out using the conditions indicated in Table 2 below:

TABLE 2
electrospinning conditions

| Parameter | Value |
|---|---|
| Applied voltage | 8 kv |
| Flow rate | 1 ml/hr |
| TCD | 12 cm |
| Tip | 18G flat tip stainless steel |

All electrospinning was performed in an environmentally controlled lab at 21° C. and 50% relative humidity.

Using these conditions, the diameters of the deposited nanofibres were controlled by varying the PMMA concentration, with mean fibre diameters resulting from PMMA concentrations of between º % and 12% shown in Table 3:

TABLE 3
Effect of PMMA concentration on mean fibre diameter

| PMMA concentration (w/v) % | Mean fibre diameter (nm) ± σ |
|---|---|
| ° | 133 ± 27 |
| 6 | 198 ± 26 |
| 8 | 289 ± 29 |
| 10 | 392 ± 7 |
| 12 | 787 ± 71 |

### Example 1(v): Collector Stage Design

The geometry of the collector stage was studied to determine the effect of the overall structure of the resultant nanofibre network. Four stage designs were investigated (see FIG. 3), namely 3a) flat; (b) ring; (c) parallel strip; and (d) cross strip.

The flat metal plate collector shown in FIG. 3(a) was the simplest stage geometry and yielded a mixture of straight and regularly oscillating nanofibres. As can be seen in FIG. 3(a), the amplitude of the oscillation was seen to fade along the length of the fibre eventually disappearing altogether. The ring collector configuration shown in FIG. 3(b) consists of a grounded copper ring on an insulating base with the sample placed at the centre of the ring. Fibres deposited on the ring itself are structured similarly to those deposited on the plate collector. Within the central region of the ring, however, the oscillations in fibre shape are no longer present and only randomly-oriented linear fibres are observed. As the charged fluid jet approaches the collector, it preferentially deposits on the grounded ring structure and avoids the insulating central region. However, the chaotic flight path of the jet inevitably directs some fibres toward the centre of the ring and attractive electrostatic forces influence the jet to reach across to the grounded ring edge. This additional force stretches out any residual bending instabilities in the jet structure resulting in straight fibres. A similar effect is observed when using parallel strip or cross strip stage designs as shown in FIGS. 3 (c) and (d) respectively.

Fibre angle histograms were measured from networks fabricated using a plate collector; and from those fabricated using a ring collector. A random angle distribution was observed in both cases with calculated averages and standard deviations closely approximating expected random average angle values of 90°±º 5°. Fibre angle analysis of a network fabricated from a parallel strip stage showed a sharp distribution centred at 90°±1.6°. A bimodal distribution was observed in the angle distribution measured from a cross strip fabricated network; two distinct fibre populations were observed centred at 0.3°±2º ° ° and 89.7°±1.6° corresponding to horizontal and vertical fibres respectively. Due to the rapid rate of deposition and poor reproducibility of fibre density between samples, the parallel and cross strip stage designs were not utilised further in this work. Both the plate and ring collectors demonstrated a relatively slow deposition rate allowing for control over the area coverage by varying the electrospinning process time and so these stage designs were used in further studies.

### Example 2: Depositing the First Metal

Once the PMMA nanofibre network is deposited on the substrate, the pattern of the nanofibre network is then transferred onto the underlying polymer film. This is performed by depositing a layer of a first metal onto the patterned layer.

A coated substrate including a patterned layer comprising a nanofibre network structure was prepared as in Example 1, using 6% PMMA on a plate collector. A º 0 nm titanium layer was deposited on the patterned layer using an e-beam vacuum system (Temescal FC-2000 e-beam vacuum) and the results of this deposition step are shown in Figure º (a). Figure º (a) shows that the exposed areas of the PS film were evenly coated in titanium while the nanofibres acted as masks during the deposition step.

### Example 3: Solvent Development

The metallised sample from Example 2 was sonicated in glacial acetic acid (Merck >99%) at 85 kHz at low power for 15 seconds and then lightly agitated in deionised H₂O for 30 seconds. This development step exploits the orthogonal solubilities of PS and PMMA—acetic acid is an excellent solvent for PMMA and a non-solvent for PS and so readily dissolves the nanofibres while leaving the patterned film intact. The developed Ti-PS template is shown in Figure º (b).

### Example 4: Annealing

At some fibre junctions, titanium was observed to have partially deposited underneath the edges of the nanofibre resulting, in a small percentage of cases in a narrowed structure (although the template width always returned to match the original fibre diameter within a micron). It was considered that a potential cause for this behaviour could be the suspension of weakly adhered fibres above the surface of the film from residual static charge, allowing the metal vapour cloud to partially diffuse under the fibre edges during deposition. In order to determine whether this effect could be mitigated, annealing experiments were carried out on the patterned layer before performing the metal deposition step. Figure º (c) shows a developed template which was subjected to an annealing step at 80° C. for 5 minutes before titanium deposition and Figure (d) for a developed template which was subjected to an annealing step at 100° C. for 5 minutes. Figure (d) shows that the PMMA fibres have visibly sunk into the underlying PS film and the development process has failed due to the conformal nature of the titanium film. Figure º (c) however shows an ideal Ti-PS junction geometry—no necking junctions were observed at any other junctions for samples subjected to these annealing conditions, indicating that this optional annealing step can mitigate deposition of titanium under the nanofibres, providing clean Ti-PS junctions.

### Example 5: Oxygen Plasma Etching

Following the solvent development step, the non-metallised areas of PS (i.e. which had previously been masked by the removed nanofibres) were etched to expose the underlying glass substrate. Oxygen plasma etching was carried out using a Diener Pico Plasma System with an O₂ pressure of 0.23 Torr and a RF power of 50 W. The highly reactive oxygen ions and radical species generated within the plasma reacted with the exposed PS to form volatile carbon oxides and water which were then pumped out of the chamber. A polystyrene etch rate of 10 nm/min was achieved and the passivation of the titanium to its non-volatile oxides allowed for a highly selective etch and no mask deterioration was observed over any etch time investigated.

FIG. 5 (a) shows a high angle SEM image of an unetched Ti-PS template with a nanofibre patterned trench visible perpendicular to the sample edge. After a 15 minute etch time, the initial removal of PS within the trench is evident as shown in FIG. 5(b). After 30 minutes, the PS was found to be etched down to the underlying substrate as shown in FIG. 5(c). An additional 30 minute etch resulted in the formation of a significant undercut of the PS film as shown in FIG. 5(d). The presence of an undercut is a desirable trait for deposition templates as it prevents any contact between the mask and the deposited material allowing for a clean lift off (Kaspar C. et al. J. Vac. Sci. Technol. B 35(6), November/December 2017, 06G501-1-06G501-6; Zhong Y. et al Chinese Journal of Electronics, vol. 25, no. 2, pp. 199-202, 3 2016).

### Example 6: Deposition of Second Metal

A templated patterned from PMMA nanofibres with an average diameter of º 50 nm was prepared as outlined in Examples 1 to 5 above, including the optional annealing step. 50 nm aluminium was deposited at a rate of 1 Å/s using a Temescal FC-2000 e-beam vacuum deposition system.

### Example 7: Lift-Off

After metallisation in Example 6 above, the sample was submerged in 500 ml of NMP and left overnight at 90° C. The sample was then rinsed in a deionised water bath, then in an ethanol bath and then dried in a nitrogen stream.

### Example 8: Effect of Nanowire Density

The performance of aluminium NWN devices with varying nanowire densities (190 nm, 80 nm, and º 0 nm) was investigated. As expected for lower deposition thicknesses, the sheet resistance was observed to shift to higher values while the transmission remained unaffected. Networks with 97.º % transmittance but with AI thicknesses of 190 nm, 80 nm and º 0 nm were studied in triplicate. Results demonstrate the versatility of this fabrication technique for the production of TC materials with tuneable properties. The transmission of the device is directly proportional to the density of nanofibres which can be easily controlled by the duration of electrospinning time; the sheet resistance can then be set to the desired value by the thickness of aluminium deposited. This allows the properties of transparency and sheet resistance to be tailored independently, allowing for total control over device behaviour.

### Example 9: Preparation of Aluminium Nanowire Network

Following the optimisation of the aluminium deposition and characterisation of individual nanowires, aluminium nanowire networks were prepared as follows:

A glass substrate was cleaned in an ultrasonic bath for 5 minutes in sequential acetone, DI water and IPA baths and dried under nitrogen flow. PS (150 k Mw) 6% (w/v) solution PS in toluene was spin coated at º 000 rpm for º 5 seconds and the coated substrate was annealed at 130° C. for 30 minutes.

A 6% solution of PMMA (w/v % 350 k Mw) and 5% CTAB (w/w % with respect to PMMA) in DMF was electrospun over the substrate using a 18 gauge stainless steel needle, a flow rate of 1 ml/hr, an applied voltage of 8 kV and a tip collector distance of 13 cm. The patterned substrate was annealed at 80° C. for 5 minutes and allowed to cool.

The substrate was metallised with º 0 nm of titanium using a Temescal FC-2000 E-beam evaporator and agitated in glacial acetic acid for 15 seconds and rinsed in DI water for a further 30 seconds to selectively remove the metallised fibres. A plasma etch was performed using a Diner PICO barrel Asher at 200 W power and 0.3 mbar Oxygen for 2 etch sessions of 30 minutes each with a 5 minute cooling time between.

The desired thickness of aluminium was deposited using a Temescal FC-2000 E-beam evaporator and lift off performed in 1165 NMP based developer overnight at 80° C. Finally, the substrate was rinsed sequentially in DI water twice, then ethanol and dried in a nitrogen flow.

### Example 10: Evaluation of Transparent Conductor Performance

The performance of Aluminium nanowire networks fabricated on transparent substrates was investigated. PMMA nanofibre networks of varying density were electrospun from 6% PMMA CTAB-DMF solutions using a disk and a plate collector stage to pattern PS coated glass and quartz substrates with linear and curvilinear wire morphologies respectively. Deposition templates were fabricated from these networks with an average width of 187±17 nm and a 190 nm layer of aluminium was deposited at 10 Å/s on each. After lift-off, a shadow mask with rows of 1 mm square contact pads was placed over the substrate and 250 nm of AI with a 5 nm Ti adhesion layer was deposited. These contact pads were used to measure the sheet resistance at multiple areas over the samples using a four point probe technique. The optical transmission was measured at adjacent areas using a Lambda 1050 spectrometer and normalised against the bare glass substrate reference transmission.

The performance of the aluminium nanowire networks was compared with known aluminium nanowire-based transparent conductors, as described in Table 4. All reference devices were fabricated with seamless junction geometries. The results are shown in FIG. 6. Both linear and curvilinear wire morphologies considerably outperformed the prior art networks in terms of both conductivity and transmittance. The improved performance may be attributed, at least in part, to the higher cross-sectional ratio achieved for the NWNs prepared by the method of the present invention, i.e. a greater thickness of aluminium can be achieved for the same area coverage. Additionally, the quality of evaporated metal films depends heavily on the type of substrate material used, and reference 3 (Cui et al.) reported that increased resistivity values above bulk were observed for metal that was deposited directly onto polymer nanofibres.

TABLE 4
Prior art aluminium-based networks

| Prior Art Reference | Procedure |
|---|---|
| 1. Li, Y., Chen, Y., Qiu, M., Yu, H., | Al film deposited on a glass substrate. Partial |
| Zhang, X., Sun, X.W. and Chen, R., | anodisation performed halting just after pore |
| 2016. Preparation of aluminum | formation reached the underlying substrate. After |
| nanomesh thin films from an anodic | etching of the oxide, a thin conductive Al film with |
| aluminum oxide template as | close packed holes remained and the size of the |
| transparent conductive electrodes. | openings was varied by extended anodisation time. |
| Scientific reports, 6(1), pp.1-7. | |
| 2.Azuma, K., Sakajiri, K., | Tokita et al. deposited a random curvilinear network of |
| Matsumoto, H., Kang, S., | electrospun PS nanofibres onto a 50 nm Al film and |
| Watanabe, J. and Tokita, M., 2014. | after annealing to fuse the fibre junctions performed a |
| Facile fabrication of transparent | KOH etch yielding a network of 500 nm wide Al ribbons |
| and conductive nanowire networks | |
| by wet chemical etching with an | |
| electrospun nanofiber mask | |
| template. Materials Letters, 115, | |
| pp.187-189. | |
| 3. Wu, H, Kong, D., Ruan, Z., Hsu, | Cui et al. also used electrospinning to fabricate a linear |
| P.C., Wang, S., Yu, Z., Carney, TJ., | freestanding network of 400 nm diameter PVA |
| Hu, L, Fan, S. and Cui, Y., 2013. A | nanofibres mounted on a copper ring collector, |
| transparent electrode based on a | aluminium was then thermally evaporated onto this |
| metal nanotrough network. Nature | structure at a thickness of 100 nm and transferred onto |
| nanotechnology, 8(6), p.421. | a transparent substrate to give an Al nanotrough |
| | network |

The performance of the aluminium nanowire networks prepared according to the invention was then compared with a prior art ITO network and a selection of alternative known TC materials, details of which can be found in Table 5 and the results of which are shown in FIG. 7. Again, both linear and curvilinear wire morphologies showed superior performance to almost all other materials compared, including ITO.

TABLE 5
prior art devices

| Prior Art Reference | Procedure |
|---|---|
| 1. Bellet, D., Lagrange, M., | Ag nanowires with average diameter of 117 nm and |
| Sannicolo, T., Aghazadehchors, S., | average length of 42.5 microns were grown using a |
| Nguyen, V.H., Langley, D.P., Munoz- | polyol solution synthesis and spin coated into a |
| Rojas, D., Jimenez, C., Brechet, Y. | network and thermally annealed. |
| and Nguyen, N.D.,2017. | |
| Transparent electrodes based on | |
| silver nanowire networks: From | |
| physical considerations towards | |
| device integration. Materials, 10(6), | |
| p.570. | |
| 2. Ye, S., Rathmell, A.R., Stewart, | Non-tapered Cu nanowires were fabricated using a |
| I.E., Ha, Y.C., Wilson, A.R., Chen, Z. | seeded growth method in low EDA |
| and Wiley, B.J., 2014. A rapid | (ethylenediamine) concentration solution and spray |
| synthesis of high aspect ratio | deposited into a network. |
| copper nanowires for high- | |
| performancetransparent | |
| conducting films. Chemical | |
| communications, 50(20), pp.2562- | |
| 2564. | |
| 3. Wu, H., Kong, D., Ruan, Z., Hsu, | PVA nanofibres were electrospun onto a ring |
| P.C., Wang, S., Yu, Z., Carney, T.J., | collector and copper metal was thermally |
| Hu, L, Fan, S. and Cui, Y., 2013. A | evaporated onto the free standing network |
| transparent electrode based on a | structure. The PVA template was dissolved using |
| metal nanotrough network. Nature | deionised water and metallic network was stamp |
| nanotechnology, 8(6), p.421. | transferred onto transparent substrate. |
| 4. Langley, D., Giusti, G., Mayousse, | High temperature co-sputtered film in vacuum |
| C., Celle, C., Bellet, D. and Simonato, | conditions. |
| J.P., 2013. Flexible transparent | |
| conductive materials based on | |
| silver nanowire networks: a review. | |
| Nanotechnology, 24(45), p.452001. | |
| 5. Aryal, M., Geddes, J., Seitz, O., | Patented roll to roll UV photolightography process |
| Wassei, J., Mc Mac kin, I. and Kobrin, | (Rolith) and metal deposition and lift off. |
| B., 2014, June. 16.1: Sub-Micron | |
| Transparent Metal Mesh Conductor | |
| for Touch Screen Displays. In SID | |
| Symposium Digest of Technical | |
| Papers (Vol. 45, No. 1, pp. 194-196). | |

### Example 11: Evaluation of Performance on Flexible Substrate

The performance of aluminium nanowire networks fabricated on flexible substrates was investigated. An aluminium nanowire network with an average wire width of 196 nm and 100 nm thickness on a 200 μm PET substrate was prepared as described in Example 8. As shown in FIG. 8, conductive silver paste contacts were placed at the ends of the device and the baseline resistance of the device was measured in the flat state (FIG. 8(i)). The centre of the strip was then bent around a plastic rod with a radius of 5 mm to flex the device to its known bending radius. The device was returned to the flat state and its resistance was measured again and compared against the original baseline. The process was repeated for 100 cycles, and the results, where R/R₀ is the ratio of the measured sheet resistance to the original sheet resistance, is shown in FIG. 9 and suggest stable device performance during flexing.

### Example 12: Evaluation with Different Materials

The performance of nanowire networks prepared using the method of the invention was investigated for a range of materials. In these studies, nanowire networks were prepared using the materials shown in Table 6 below according to the general procedure set out in Example 9. In Example 12(v), sputtering of the second metal was performed in a Cressington 208HR vacuum sputterer at room temperature and under 0.05 Mbar argon pressure.

TABLE 6
Fabrication of alternative nanowire networks

| | | | | | First metal | | | Second metal | Lift |
|---|---|---|---|---|---|---|---|---|---|
| Example | | First | Second | First | deposition | Development | Second | deposition | off |
| Number | Substrate | polymer | polymer | metal | method | solvent | metal | method | Solvent |
| (i) | Glass | PS | PMMA | Ti | E-Beam | Acetic acid | Al | E-Beam | NMP |
| (ii) | Glass | PS | PMMA | Ti | E-Beam | Acetic acid | Ti | E-Beam | NMP |
| (iii) | Glass | PS | PMMA | Ti | E-Beam | Acetic acid | Cu | E-Beam | NMP |
| (iv) | Glass | PS | PMMA | Ti | E-Beam | Acetic acid | Ni | E-Beam | NMP |
| (v) | Glass | PS | PMMA | Ti | E-Beam | Acetic acid | Pt | Sputter | NMP |
| (vi) | PET | PMMA | PVP | Ti | E-Beam | Ethanol | Al | E-Beam | Acetone |
| (vii) | PEN | PS | PMMA | Ti | E-Beam | Acetic acid | Al | E-Beam | NMP |

All of the resultant nanowire networks prepared in Table 6 demonstrated quantitative lift off and full connectivity across the network area.

Overall, comparative studies with both other aluminium networks and alternative materials, indicate improved performance for the nanofibre networks of the invention. The method uses robust techniques, such as spin coating, metal deposition and plasma etching, which are highly scalable and widely-used, suggesting industrial scalability of the overall process. A wide number of materials can be used, including AI, which is highly available and significantly less costly than other materials, such as silver or gold. In some embodiments, the use of aluminium is particularly advantageous as the superb passivation on aluminium eliminates corrosion problems that have plagued alternative known devices. The fabricated networks are continuous and comprised of seamless junctions, ensuring maximum possible connectivity and conductivity. The optical and electrical properties of the network can be controlled independently, i.e. the optical transmission of the network can be controlled by controlling the density of the wires in the network, while the conductivity of the network can be controlled by controlling the thickness or aspect ratio of the wires in the network. This allows the networks to be tailored for the application of interest. The networks can be prepared on either rigid or flexible substrates.

All of the features disclosed in this specification (including any accompanying claims, abstract and drawings), and/or all of the steps of any method or process so disclosed, may be combined in any combination, except combinations where at least some of such features and/or steps are mutually exclusive. Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features. The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations).

It will be appreciated that various embodiments of the present disclosure have been described herein for purposes of illustration, and that various modifications may be made without departing from the scope of the present disclosure. Accordingly, the various embodiments disclosed herein are not intended to be limiting, with the true scope being indicated by the following claims.

1. A method of preparing a conductive nanowire network, the method comprising:
(a) providing a substrate coated with a film of a first polymer;
(b) depositing nanofibers of a second polymer onto the film to form a patterned layer comprising a nanofibre network structure;
(c) depositing a layer of a first metal onto the patterned layer;
(d) performing a solvent development step to selectively remove the nanofibers leaving a negative pattern in the first metal layer exposing the first polymer film;
(e) performing an etching step to remove the exposed polymer film;
(f) depositing a second metal or oxide thereof onto the negative pattern to form a templated nanowire network;
(g) performing a lift-off step to expose the nanowire network.

2. A method as claimed in claim 1, wherein the step of depositing nanofibers of a second polymer onto the film is performed by electrospinning.

3. A method as claimed in claim 1, wherein the step of depositing a layer of a first metal onto the patterned layer is performed by a vacuum deposition or atmospheric deposition process.

4. A method as claimed in claim 1, wherein the etching step is performed by oxygen plasma etching.

5. A method as claimed in claim 1, wherein the step of depositing a second metal or oxide thereof onto the negative pattern is performed by a vacuum deposition or atmospheric deposition process.

6. A method as claimed in claim 1, wherein the first polymer and the second polymer are orthogonal in solubility.

7. A method as claimed in claim 1, wherein the substrate coated with a film of a first polymer has been formed by spin coating.

8. A method as claimed in claim 1, wherein the first polymer is selected from polystyrene (PS) and polymethylacrylate (PMMA).

9. A method as claimed in claim 1, wherein the second polymer is selected from polymethylmethacrylate (PMMA), polyvinyl alcohol (PVA), polyvinyl pyrrolidone (PVP), polyethylene oxide (PEO) and polyvinyl acetate (PVAc).

10. A method as claimed in claim 1, wherein the first metal is selected from titanium, chromium, cobalt, gold, palladium, platinum, silver, tantalum, tungsten and silicon.

11. A method as claimed in claim 10, wherein the first metal is titanium.

12. A method as claimed in claim 1, wherein the second metal or oxide thereof is selected from gold, silver, copper, nickel, titanium, chromium, aluminium, platinum, silicon, titanium dioxide, silicon dioxide and nickel oxide.

13. A method as claimed in claim 12, wherein the second metal is aluminium.

14. A method as claimed in claim 1, wherein the lift-off step comprises dissolving the first polymer with solvent to remove the first polymer layer and remaining first metal.

15. A method as claimed in claim 1, wherein the lift-off step comprises immersing the templated metal nanowire network in a lift-off solvent.

16. A method as claimed in claim 15, wherein the lift-off solvent is selected from acetone and N-methyl-2-pyrrolidone (NMP).

17. A method as claimed in claim 1, further comprising step b(1) of annealing the patterned layer.

18. A method as claimed in claim 1, wherein the substrate is a flexible substrate.

19. A conductive metal network prepared by the method of claim 1.
